(19) United States
(12) Patent Application Publication
(10) Pub. No.: US 2026/0090214 A1
(43) Pub. Date: Mar. 26, 2026

(54) DISPLAY PANEL, DISPLAY APPARATUS, AND PREPARATION METHOD FOR DISPLAY PANEL

(71) Applicant: Hefei Visionox Technology Co., Ltd., Hefei (CN)

(72) Inventor: Zhiwei ZHOU, Hefei (CN)

(73) Assignee: Hefei Visionox Technology Co., Ltd., Hefei (CN)

(21) Appl. No.: 19/334,937

(22) Filed: Sep. 21, 2025

(30) Foreign Application Priority Data
Sep. 26, 2024 (CN) 202411358219.9

(51) Int. Cl. H10K 59/122; H10K 59/80

(52) U.S. Cl. CPC H10K 59/122; H10K 59/80515; H10K 59/80521

(57) ABSTRACT

The present application discloses a display panel, a display apparatus, and a preparation method for a display panel. The display panel includes a substrate, an isolation structure, and a light-emitting layer. A second active area is configured to accommodate a photosensitive assembly, and the second active area has a light transmittance greater than a light transmittance of a first active area, thereby improving the photosensitive effect of the second active area. A first layer and a second layer are disposed to form the isolation structure. An extension distance corresponding to designated light-emitting units of light-emitting units in the second active area is less than or equal to an extension distance corresponding to other light-emitting units in the first active area that emit the same color as the designated light-emitting units, resulting in an increased lap area between a first electrode in the second active area and the isolation structure.

### CROSS-REFERENCES TO RELATED APPLICATIONS

The present application claims priority to the Chinese Patent Application No. 202411358219.9, filed on Sep. 26, 2024, and the entire contents of the aforementioned application are hereby incorporated by reference in its entirety.

### TECHNICAL FIELD

The present application relates to the field of display, and particularly to a display panel, a display apparatus, and a preparation method for a display panel.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and a wide range of applications.

However, the usage performance of conventional OLED display products needs to be improved.

### SUMMARY

Embodiments of the present application provide a display panel, a display apparatus, and a preparation method for a display panel, which are intended to improve the usage performance of the display panel.

An embodiment of a first aspect of the present application provides a display panel, where the display panel includes a first active area and a second active area, the first active area having a light transmittance less than a light transmittance of the second active area. The display panel includes: a substrate; at least an isolation structure located on the substrate, where the at least an isolation structure encircles a plurality of isolation openings, and the at least an isolation structure includes a first layer and a second layer located on a side of the first layer that faces away from the substrate, with an orthographic projection of the first layer on the substrate being within an orthographic projection of the second layer on the substrate; and a light-emitting layer located on the substrate, the light-emitting layer including a plurality of light-emitting units located in the isolation openings, where a distance between an edge of the orthographic projection of the first layer on the substrate that is close to the light-emitting unit and an edge of the orthographic projection of the second layer on the substrate that is close to the same light-emitting unit is an extension distance, and the extension distance corresponding to designated light-emitting units of the plurality of light-emitting units in the second active area is less than or equal to the extension distance corresponding to other light-emitting units in the first active area that emit the same color as the designated light-emitting units.

An embodiment of a second aspect of the present application provides a display panel, where the display panel includes a first active area and a second active area adjacent to the first active area. The display panel further includes: a substrate; at least an isolation structure located on the substrate, where the at least an isolation structure encircles a plurality of isolation openings, and the isolation structure includes a first layer and a second layer located on a side of the first layer that faces away from the substrate, the second layer including a protrusion that protrudes relative to the first layer; and a light-emitting layer located on the substrate, the light-emitting layer including a plurality of light-emitting units located in the isolation openings, where a width of the protrusion corresponding to designated light-emitting units of the plurality of light-emitting units in the second active area is less than or equal to a width of the protrusion corresponding to other light-emitting units in the first active area that emit the same color as the designated light-emitting units.

An embodiment of a third aspect of the present application provides a display panel, where the display panel includes a first active area and a second active area, the first active area having a light transmittance less than a light transmittance of the second active area. The display panel includes: a substrate; at least an isolation structure located on the substrate, where the at least an isolation structure encircles a plurality of isolation openings; a light-emitting layer located on the substrate, the light-emitting layer including a plurality of light-emitting units located in the isolation openings; and a first electrode layer located on a side of the light-emitting layer that faces away from the substrate, the first electrode layer including a plurality of first electrodes spaced apart from each other, where the first electrodes are electrically connected to the at least an isolation structure; and among the corresponding first electrodes where the light-emitting units of the same color are located, a climbing height, on the at least an isolation structure, of the first electrode located in the first active area is less than or equal to a climbing height, on the at least an isolation structure, of the first electrode located in the second active area.

An embodiment of a fourth aspect of the present application provides a display apparatus, including a display panel of any one of the above-described implementations.

An embodiment of a fifth aspect of the present application provides a preparation method for a display panel, where the display panel includes a first active area and a second active area adjacent to the first active area. The method includes: preparing at least an isolation structure on a substrate, where the at least an isolation structure encircles a plurality of isolation openings, and the isolation structure includes a first layer and a second layer located on a side of the first layer that faces away from the substrate, with an orthographic projection of the first layer on the substrate being within an orthographic projection of the second layer on the substrate, and a distance between an edge of the orthographic projection of the first layer on the substrate that faces the isolation opening and an edge of the orthographic projection of the second layer on the substrate that faces the same isolation opening being an extension distance; and preparing a light-emitting layer on the substrate, the light-emitting layer including a plurality of light-emitting units located in the isolation openings, where the extension distance corresponding to designated light-emitting units of the plurality of light-emitting units in the second active area is less than or equal to the extension distance corresponding to other light-emitting units in the first active area that emit the same color as the designated light-emitting units.

According to the display panel of the embodiment of the present application, the display panel includes the substrate, the isolation structure, and the light-emitting layer. The second active area is configured to accommodate a photosensitive assembly, and the second active area has a light transmittance greater than a light transmittance of the first active area, thereby improving the photosensitive effect of the second active area. The first layer and the second layer are disposed to form the isolation structure, the orthographic projection, on the substrate, of the first layer disposed close to the substrate is within the orthographic projection of the second layer on the substrate, the area of the second layer is greater than the area of the first layer, and the second layer covers the surface of the first layer that is close to the second layer, in which case the first layer is recessed relative to the second layer in a direction facing away from the isolation opening. When the light-emitting layer is prepared, the light-emitting layer causes a large drop at an edge of the isolation structure, the first layer is recessed relative to the second layer, and the light-emitting layer is difficult to connect at the edge of the isolation structure, resulting in breakage. The light-emitting layer breaks to form light-emitting units that are disconnected from each other, thereby reducing crosstalk of carriers in the light-emitting layer, and improving the display effect of the display panel; and the light-emitting unit may be prepared without the use of a precision mask, reducing the development and use of the precision mask and lowering the preparation cost. The extension distance corresponding to designated light-emitting units of the plurality of light-emitting units in the second active area is less than or equal to the extension distance corresponding to other light-emitting units in the first active area that emit the same color as the designated light-emitting units. When a first electrode is prepared, the peripheral side of the first electrode laps a sidewall of the first layer of the isolation structure. The light-emitting units in the second active area correspond to a smaller extension distance of the isolation structure, resulting in an increased lap area between the first electrode in the second active area and the isolation structure, and thus a reduced lap impedance between the first electrode in the second active area and the isolation structure. A difference between a lap impedance between the first electrode in the first active area and the isolation structure and a lap impedance between the first electrode in the second active area and the isolation structure is reduced, thereby mitigating undesirable phenomenon of dark streaks appearing in the second active area due to a large difference between the lap impedance between the first electrode in the first active area and the isolation structure and the lap impedance between the first electrode in the second active area and the isolation structure, and thus improving the usage performance of the display panel.

### BRIEF DESCRIPTION OF THE DRAWINGS

Embodiments of the present application will become more clear upon reading the following detailed description of non-limiting embodiments with reference to the accompanying drawings, where identical or similar reference signs indicate identical or similar features and the drawings are not necessarily drawn to scale.

FIG. 1 is a schematic top view of a display panel according to an embodiment of the present application;

FIG. 2 is a partial cross-sectional view of a first active area according to an embodiment of the present application;

FIG. 3 is a partial cross-sectional view of a second active area according to an embodiment of the present application;

FIG. 4 is a partial top view of a display panel according to an embodiment of the present application;

FIG. 5 is a partial cross-sectional view of a first active area according to another embodiment;

FIG. 6 is a partial cross-sectional view of a second active area according to another embodiment;

FIG. 7 is a partial cross-sectional view of a first active area according to still another embodiment;

FIG. 8 is a partial cross-sectional view of a second active area according to still another embodiment;

FIG. 9 is a partial cross-sectional view of a first active area according to yet another embodiment;

FIG. 10 is a partial cross-sectional view of a second active area according to yet another embodiment;

FIG. 11 is a partial cross-sectional view of a first active area according to still yet another embodiment;

FIG. 12 is a partial cross-sectional view of a second active area according to still yet another embodiment;

FIG. 13 is a partial cross-sectional view of a first active area according to still yet another embodiment;

FIG. 14 is a partial cross-sectional view of a second active area according to still yet another embodiment;

FIG. 15 is a partial cross-sectional view of a first active area according to still yet another embodiment;

FIG. 16 is a partial cross-sectional view of a second active area according to still yet another embodiment;

FIG. 17 is a partial cross-sectional view of a first active area according to still yet another embodiment;

FIG. 18 is a partial cross-sectional view of a second active area according to still yet another embodiment;

FIG. 19 is a partial cross-sectional view of a first active area according to still yet another embodiment;

FIG. 20 is a partial cross-sectional view of a first active area according to still yet another embodiment;

FIG. 21 is a partial cross-sectional view of a second active area according to still yet another embodiment; and

FIG. 22 is a schematic flowchart of a preparation method for a display panel according to an embodiment of the present application.

### DETAILED DESCRIPTION OF THE EMBODIMENTS

Features and exemplary embodiments in various aspects of the present application will be described in detail below. In order to make the objectives, technical solutions, and advantages of the present application clearer, the present application will be further described in detail below with reference to the accompanying drawings and specific embodiments. It should be understood that the specific embodiments described herein are merely configured to explain the present application and are not configured to limit the present application. The present application may be implemented without some of these specific details. The following description of the embodiments is merely to provide a better understanding of the present application by illustrating examples of the present application.

It should be noted that, herein, relational terms such as “first” and “second” are only used to distinguish one entity or operation from another entity or operation, and do not necessarily require or imply that such an actual relationship or order exists between these entities or operations. Furthermore, the terms “comprises”, “includes” or any other variant thereof are intended to cover non-exclusive inclusion, and a process, method, object or equipment including a series of elements not only includes those elements, but further includes other elements not explicitly listed, or further includes elements inherent to such process, method, object or equipment. If no more limitations are made, an element limited by “including . . . ” does not exclude other identical elements existing in the process, the method, the article, or the device which includes the element.

It should be understood that in the description of the structure of a component, a layer or region referred as being located “above” or “over” another layer or region may be directly on the other layer or region, or there may be other layers or regions between the layer or region and the other layer or region. Moreover, if the component is turned over, the layer or region is located “below” or “under” the other layer or region.

The embodiments of the present application provide a display panel, a display apparatus, and a preparation method for a display panel. Various embodiments of the display panel, the display apparatus, and the preparation method for a display panel will be illustrated below with reference to the drawings.

The embodiments of the present application provide a display panel, which may be an organic light-emitting diode (OLED) display panel.

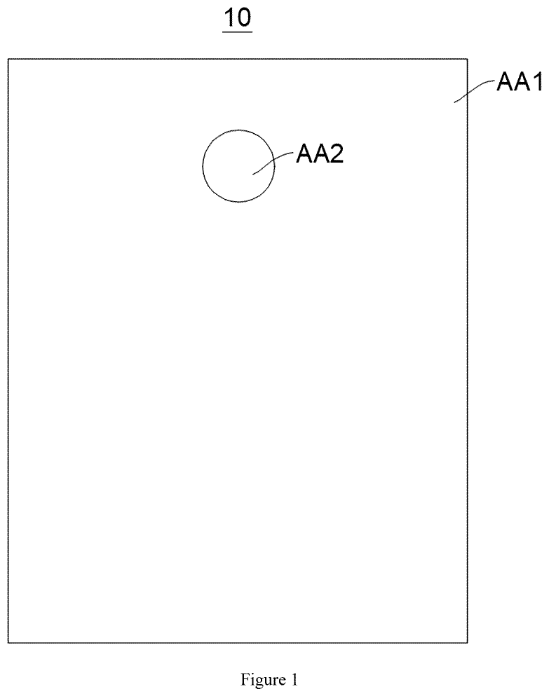

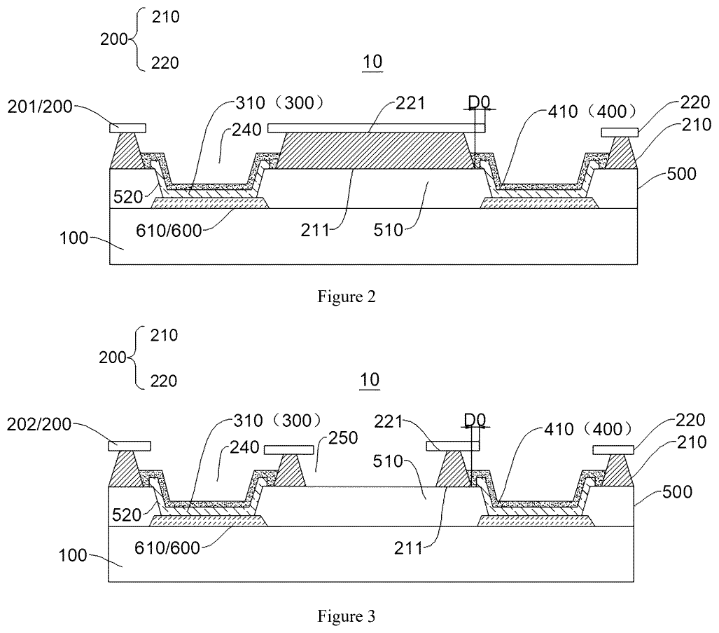

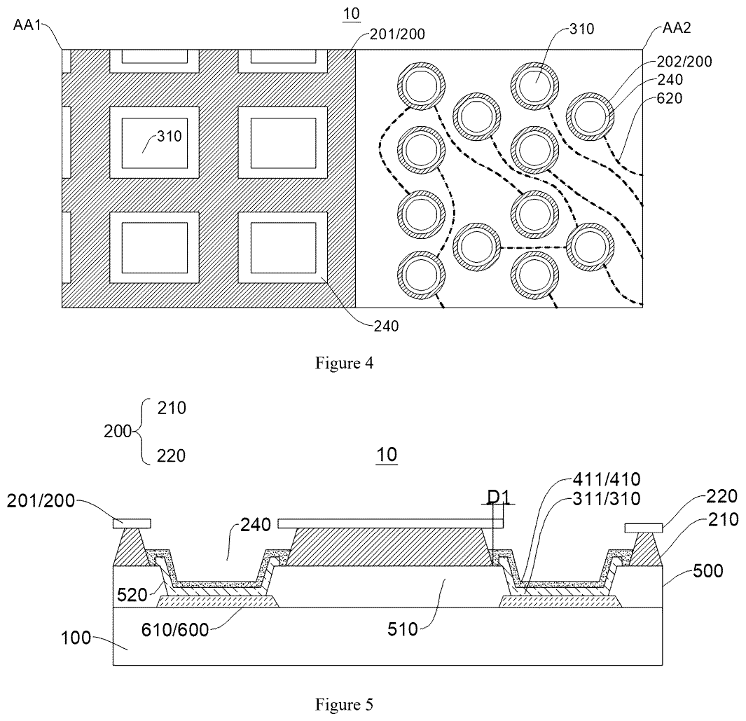

Referring to FIGS. 1 to 4, FIG. 1 is a schematic top view of a display panel according to an embodiment of the present application; FIG. 2 is a partial cross-sectional view of a first active area according to an embodiment of the present application; FIG. 3 is a partial cross-sectional view of a second active area according to an embodiment of the present application; and FIG. 4 is a partial top view of a display panel according to an embodiment of the present application.

As shown in FIGS. 1 to 4, an embodiment of a first aspect of the present application provides a display panel 10, where the display panel 10 includes a first active area AA1 and a second active area AA2, the first active area AA1 having a light transmittance lower than a light transmittance of the second active area AA2. The display panel 10 includes: a substrate 100; at least an isolation structure 200 located on the substrate 100, where the at least an isolation structure 200 encircles a plurality of isolation openings 240, and the isolation structure 200 includes a first layer 210 and a second layer 220 located on a side of the first layer 210 that faces away from the substrate 100, with an orthographic projection of the first layer 210 on the substrate 100 being within an orthographic projection of the second layer 220 on the substrate 100; and a light-emitting layer 300 located on the substrate 100, the light-emitting layer 300 including a plurality of light-emitting units 310 located in the isolation openings 240, where a distance between an edge of the orthographic projection of the first layer 210 on the substrate 100 that is close to the light-emitting unit 310 and an edge of the orthographic projection of the second layer 220 on the substrate 100 that is close to the same light-emitting unit 310 is an extension distance DO, and the extension distance DO corresponding to designated light-emitting units of the plurality of light-emitting units 310 in the second active area AA2 is less than or equal to the extension distance DO corresponding to other light-emitting units 310 in the first active area AA1 that emit the same color as the designated light-emitting units.

The extension distance DO corresponding to the light-emitting unit 310 is the extension distance DO of the isolation structure 200 on a peripheral side of the isolation opening 240 in which the light-emitting unit 310 is located, that is, the extension distance DO of the first layer 210 and the second layer 220 that is close to the light-emitting unit 310.

According to the display panel 10 of the embodiment of the present application, the display panel 10 includes the substrate 100, the isolation structure 200, and the light-emitting layer 300. The second active area AA2 is configured to accommodate a photosensitive assembly, and the second active area AA2 has a light transmittance greater than a light transmittance of the first active area AA1, thereby improving the photosensitive effect of the second active area AA2. The first layer 210 and the second layer 220 are disposed to form the isolation structure 200, the orthographic projection, on the substrate 100, of the first layer 210 disposed close to the substrate 100 is within the orthographic projection of the second layer 220 on the substrate 100, the area of the second layer 220 is greater than the area of the first layer 210, and the second layer 220 covers the surface of the first layer 210 that is close to the second layer 220, in which case the first layer 210 is recessed relative to the second layer 220 in a direction facing away from the isolation opening 240. When the light-emitting layer 300 is prepared, the light-emitting layer 300 causes a large drop at an edge of the isolation structure 200, the first layer 210 is recessed relative to the second layer 220, and the light-emitting layer 300 is difficult to connect at the edge of the isolation structure 200, resulting in breakage. The light-emitting layer 300 breaks to form light-emitting units 310 that are disconnected from each other, thereby reducing crosstalk of carriers in the light-emitting layer 300, and improving the display effect of the display panel 10; and the light-emitting unit 310 may be prepared without the use of a precision mask, reducing the development and use of the precision mask and lowering the preparation cost. The extension distance DO corresponding to designated light-emitting units of the light-emitting units 310 in the second active area AA2 is less than or equal to the extension distance DO corresponding to other light-emitting units 310 in the first active area AA1 that emit the same color as the designated light-emitting units. When a first electrode 410 is prepared, the peripheral side of the first electrode 410 laps a sidewall of the first layer 210 of the isolation structure 200. The light-emitting units 310 in the second active area AA2 correspond to a smaller extension distance DO of the isolation structure 200, resulting in an increased lap area between the first electrode 410 in the second active area AA2 and the isolation structure 200, and thus a reduced lap impedance between the first electrode 410 in the second active area AA2 and the isolation structure 200. A difference between a lap impedance between the first electrode 410 in the first active area AA1 and the isolation structure 200 and a lap impedance between the first electrode in the second active area AA2 and the isolation structure is reduced, thereby mitigating undesirable phenomenon of dark streaks appearing in the second active area AA2 due to a large difference between the lap impedance between the first electrode 410 in the first active area AA1 and the isolation structure 200 and the lap impedance between the first electrode in the second active area AA2 and the isolation structure, and thus improving the usage performance of the display panel 10.

The substrate 100 may be arranged in a variety of ways, for example, the substrate 100 may include a base substrate and an array substrate disposed on the base substrate. In one embodiment, the substrate 100 is the base substrate. In one embodiment, the substrate 100 includes a buffer layer, a support plate, etc. on a side facing away from the base substrate.

In some embodiments, the extension distances DO corresponding to a plurality of light-emitting units 310 of the same color in the first active area AA1 are the same, and/or the extension distances DO corresponding to a plurality of light-emitting units 310 of the same color in the second active area AA2 are the same.

In these embodiments, in the first active area AA1, the extension distances DO corresponding to the plurality of light-emitting units 310 of the same color are the same; and in the second active area AA2, the extension distances DO corresponding to the plurality of light-emitting units 310 of the same color are the same. The extension distance DO corresponding to the designated light-emitting units 310 in the second active area AA2 is less than or equal to the extension distance DO corresponding to the other light-emitting units 310 in the first active area AA1 that emit the same color as the designated light-emitting units. In other words, among the light-emitting units 310 of the same color, the extension distance DO corresponding to the light-emitting units 310 in the first active area AA1 is less than or equal to the extension distance DO corresponding to the light-emitting units 310 in the second active area AA2, resulting in a reduced difference between the lap impedance between the first electrode 410 in the first active area AA1 and the isolation structure 200 and the lap impedance between the first electrode in the second active area AA2 and the isolation structure.

In some embodiments, among the isolation openings 240 corresponding to the designated light-emitting units of the light-emitting units 310 of the same color, an area of an orthographic projection, on the substrate 100, of the isolation opening 240 located in the first active area AA1 is greater than or equal to an area of an orthographic projection, on the substrate 100, of the isolation opening 240 located in the second active area AA2.

The isolation opening 240 corresponding to the light-emitting unit 310 is the isolation opening 240 in which the light-emitting unit 310 is located.

In these embodiments, the area of the orthographic projection, on the substrate 100, of the isolation opening 240 located in the second active area AA2 is smaller, resulting in a reduced area of the isolation opening 240 in the second active area AA2 and thus an increased light transmission area of the second active area AA2, thereby improving the light transmittance of the second active area AA2. For example, the area of the light transmission gap 250 between the isolation structures 200 in the second active area AA2 is increased.

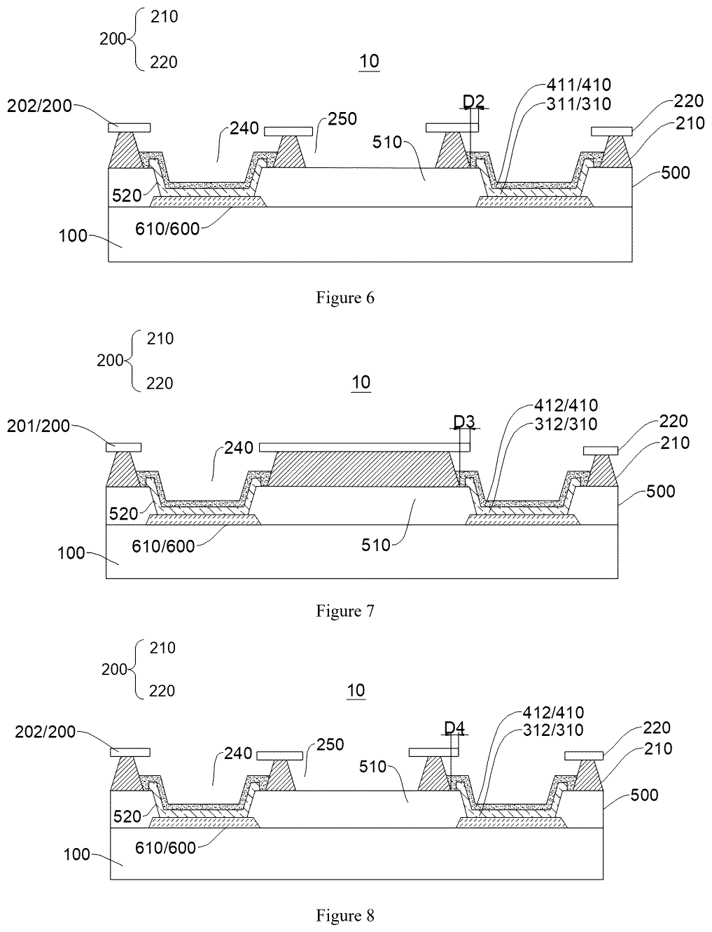

Referring to FIGS. 5 and 6, FIG. 5 is a partial cross-sectional view of a first active area according to another embodiment; and FIG. 6 is a partial cross-sectional view of a second active area according to another embodiment.

As shown in FIGS. 5 and 6, in some embodiments, the light-emitting unit 310 includes a first light-emitting unit 311. In the first active area AA1, the extension distance DO corresponding to the first light-emitting unit 311 is a first distance D1, and in the second active area AA2, the extension distance DO corresponding to the first light-emitting unit 311 is a second distance D2, the first distance D1 being greater than or equal to the second distance D2.

In these embodiments, the first distance D1 is greater than or equal to the second distance D2. In other words, the extension distance DO corresponding to the first light-emitting unit 311 in the second active area AA2 is less than or equal to the extension distance DO corresponding to the first light-emitting unit 311 in the first active area AA1, resulting in an increased lap area between the first electrode 410 corresponding to the first light-emitting unit 311 in the second active area AA2 and the isolation structure 200, and a reduced lap impedance between the first electrode 410 corresponding to the first light-emitting unit 311 in the second active area AA2 and the isolation structure 200. A difference between a lap impedance between the first electrode 410 corresponding to the first light-emitting unit 311 in the first active area AA1 and the isolation structure 200 and a lap impedance between the first electrode corresponding to the first light-emitting unit in the second active area AA2 and the isolation structure is reduced, thereby mitigating undesirable phenomenon of dark streaks appearing in the second active area AA2 due to a large difference between the lap impedance between the first electrode 410 corresponding to the first light-emitting unit 311 in the first active area AA1 and the isolation structure 200 and the lap impedance between the first electrode corresponding to the first light-emitting unit in the second active area AA2 and the isolation structure, and thus improving the usage performance of the display panel 10.

The first electrode 410 corresponding to the first light-emitting unit 311 is the first electrode 410 that covers the first light-emitting unit 311, that is, the first electrode 410 that is located in the same isolation opening 240 as the first light-emitting unit 311.

Referring to FIGS. 7 and 8, FIG. 7 is a partial cross-sectional view of a first active area according to still another embodiment; and FIG. 8 is a partial cross-sectional view of a second active area according to still another embodiment.

As shown in FIGS. 7 and 8, in some embodiments, the light-emitting unit 310 further includes a second light-emitting unit 312 spaced apart from the first light-emitting unit 311. In the first active area AA1, the extension distance DO corresponding to the second light-emitting unit 312 is a third distance D3, and in the second active area AA2, the extension distance DO corresponding to the second light-emitting unit 312 is a fourth distance D4, the third distance D3 being greater than or equal to the fourth distance D4.

In these embodiments, the third distance D3 is greater than or equal to the fourth distance D4. In other words, the extension distance DO corresponding to the second light-emitting unit 312 in the second active area AA2 is less than or equal to the extension distance DO corresponding to the second light-emitting unit 312 in the first active area AA1, resulting in an increased lap area between the first electrode 410 corresponding to the second light-emitting unit 312 in the second active area AA2 and the isolation structure 200, and a reduced lap impedance between the first electrode 410 corresponding to the second light-emitting unit 312 in the second active area AA2 and the isolation structure 200. A difference between a lap impedance between the first electrode 410 corresponding to the second light-emitting unit 312 in the first active area AA1 and the isolation structure 200 and a lap impedance between the first electrode corresponding to the second light-emitting unit in the second active area AA2 and the isolation structure is reduced, thereby mitigating undesirable phenomenon of dark streaks appearing in the second active area AA2 due to a large difference between the lap impedance between the first electrode 410 corresponding to the second light-emitting unit 312 in the first active area AA1 and the isolation structure 200 and the lap impedance between the first electrode corresponding to the second light-emitting unit in the second active area AA2 and the isolation structure, and thus improving the usage performance of the display panel 10.

The first electrode 410 corresponding to the second light-emitting unit 312 is the first electrode 410 that covers the second light-emitting unit 312, that is, the first electrode 410 that is located in the same isolation opening 240 as the second light-emitting unit 312.

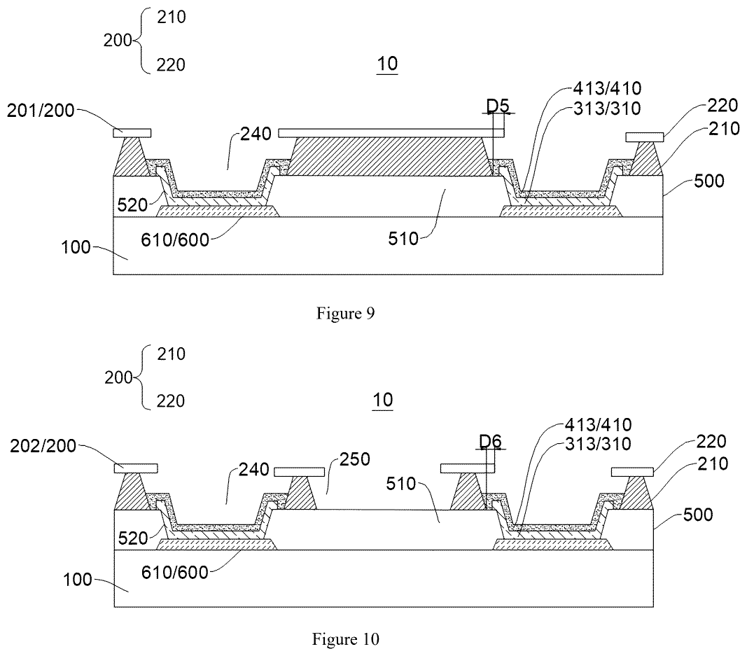

Referring to FIGS. 9 and 10, FIG. 9 is a partial cross-sectional view of a first active area according to yet another embodiment; and FIG. 10 is a partial cross-sectional view of a second active area according to yet another embodiment.

As shown in FIGS. 9 and 10, in some embodiments, the light-emitting unit 310 further includes a third light-emitting unit 313 spaced apart from the first light-emitting unit 311 and the second light-emitting unit 312. In the first active area AA1, the extension distance DO corresponding to the third light-emitting unit 313 is a fifth distance D5, and in the second active area AA2, the extension distance DO corresponding to the third light-emitting unit 313 is a sixth distance D6, the fifth distance D5 being greater than or equal to the sixth distance D6.

In these embodiments, the fifth distance D5 is greater than or equal to the sixth distance D6. In other words, the extension distance DO corresponding to the third light-emitting unit 313 in the second active area AA2 is less than or equal to the extension distance DO corresponding to the third light-emitting unit 313 in the first active area AA1, resulting in an increased lap area between the first electrode 410 corresponding to the third light-emitting unit 313 in the second active area AA2 and the isolation structure 200, and a reduced lap impedance between the first electrode 410 corresponding to the third light-emitting unit 313 in the second active area AA2 and the isolation structure 200. A difference between a lap impedance between the first electrode 410 corresponding to the third light-emitting unit 313 in the first active area AA1 and the isolation structure 200 and a lap impedance between the first electrode corresponding to the third light-emitting unit in the second active area AA2 and the isolation structure is reduced, thereby mitigating undesirable phenomenon of dark streaks appearing in the second active area AA2 due to a large difference between the lap impedance between the first electrode 410 corresponding to the third light-emitting unit 313 in the first active area AA1 and the isolation structure 200 and the lap impedance between the first electrode corresponding to the third light-emitting unit in the second active area AA2 and the isolation structure, and thus improving the usage performance of the display panel 10.

In one embodiment, the first light-emitting unit 311 is a light-emitting unit 310 that emits red light, the second light-emitting unit 312 is a light-emitting unit 310 that emits green light, and the third light-emitting unit 313 is a light-emitting unit 310 that emits blue light.

In some embodiments, the display panel 10 further includes: a first electrode layer 400 located on a side of the light-emitting layer 300 that faces away from the substrate 100.

In one embodiment, the first electrode layer 400 includes a plurality of first electrodes 410 spaced apart from each other, where the first electrodes 410 are electrically connected to the isolation structure 200.

In these embodiments, the isolation structure 200 separates the first electrode layer 400 to form first electrodes 410 spaced apart from each other, and the first electrodes 410 spaced apart from each other are electrically connected through the isolation structure 200 to form a continuous electrode to ensure normal light emission of the light-emitting unit 310.

In some embodiments, an orthographic projection of each light-emitting unit 310 on the substrate 100 is within an orthographic projection of each first electrode 410 on the substrate 100.

In these embodiments, the orthographic projection of the light-emitting unit 310 on the substrate 100 is within the orthographic projection of the first electrode 410 on the substrate 100, that is, the first electrode 410 is disposed to cover the light-emitting unit 310 to serve as the electrode of the light-emitting unit 310 to ensure normal light emission of the light-emitting unit 310, thereby improving the display effect of the display panel 10.

In one embodiment, the light-emitting unit 310 is spaced apart from the isolation structure 200, and the light-emitting unit 310 is spaced apart from the isolation structure 200, that is, the light-emitting units 310 are spaced apart from each other, thereby reducing crosstalk of carriers between the light-emitting units 310, and thus mitigating the problem of color cast in the light-emitting units 310.

In one embodiment, the area of the orthographic projection, on the substrate 100, of the first electrode 410 in the first active area AA1 is greater than or equal to the area of the orthographic projection, on the substrate 100, of the first electrode 410 in the second active area AA2. The first electrode 410 in the first active area AA1 has a larger area, and has a larger lap area with the isolation structure 200. Therefore, the extension distance DO of the isolation structure 200 that corresponds to the light-emitting unit 310 in the second active area AA2 where the first electrode 410 is smaller is set to be smaller, resulting in an increased the lap area between the first electrode 410 in the second active area AA2 and the isolation structure 200, and thus a reduced lap impedance between the first electrode 410 in the second active area AA2 and the isolation structure 200. A difference between a lap impedance between the first electrode 410 in the first active area AA1 and the isolation structure 200 and a lap impedance between the first electrode in the second active area AA2 and the isolation structure is reduced, thereby mitigating undesirable phenomenon of dark streaks appearing in the second active area AA2 due to a large difference between the lap impedance between the first electrode 410 in the first active area AA1 and the isolation structure 200 and the lap impedance between the first electrode in the second active area AA2 and the isolation structure, and thus improving the usage performance of the display panel 10.

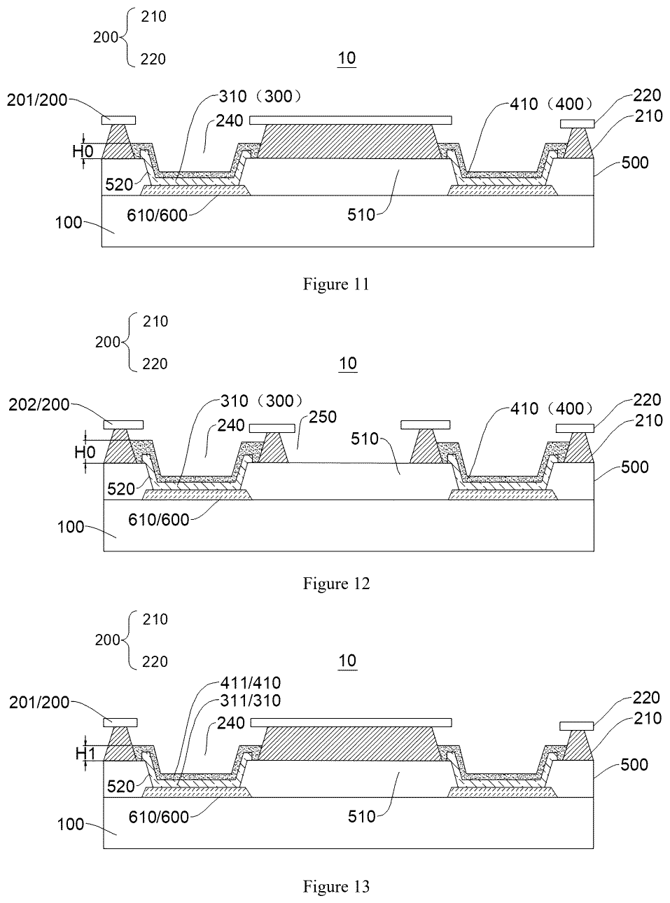

Referring to FIGS. 11 and 12, FIG. 11 is a partial cross-sectional view of a first active area according to still yet another embodiment; and FIG. 12 is a partial cross-sectional view of a second active area according to still yet another embodiment.

As shown in FIGS. 11 and 12, in some embodiments, among the corresponding first electrodes 410 where the light-emitting units 310 of the same color are located, a climbing height H0, on the isolation structure 200, of the first electrode 410 located in the first active area AA1 is less than or equal to a climbing height H0, on the isolation structure 200, of the first electrode 410 located in the second active area AA2.

In these embodiments, the first electrode 410 in the isolation opening 240 that is located in the second active area AA2 has a larger climbing height H0 on the isolation structure 200, resulting in an increased lap area between the first electrode 410 in the second active area AA2 and the isolation structure 200, and a reduced lap impedance between the first electrode 410 in the second active area AA2 and the isolation structure 200. A difference between a lap impedance between the first electrode 410 in the first active area AA1 and the isolation structure 200 and a lap impedance between the first electrode in the second active area AA2 and the isolation structure is reduced, thereby mitigating undesirable phenomenon of dark streaks appearing in the second active area AA2 due to a large difference between the lap impedance between the first electrode 410 in the first active area AA1 and the isolation structure 200 and the lap impedance between the first electrode in the second active area AA2 and the isolation structure, and thus improving the usage performance of the display panel 10.

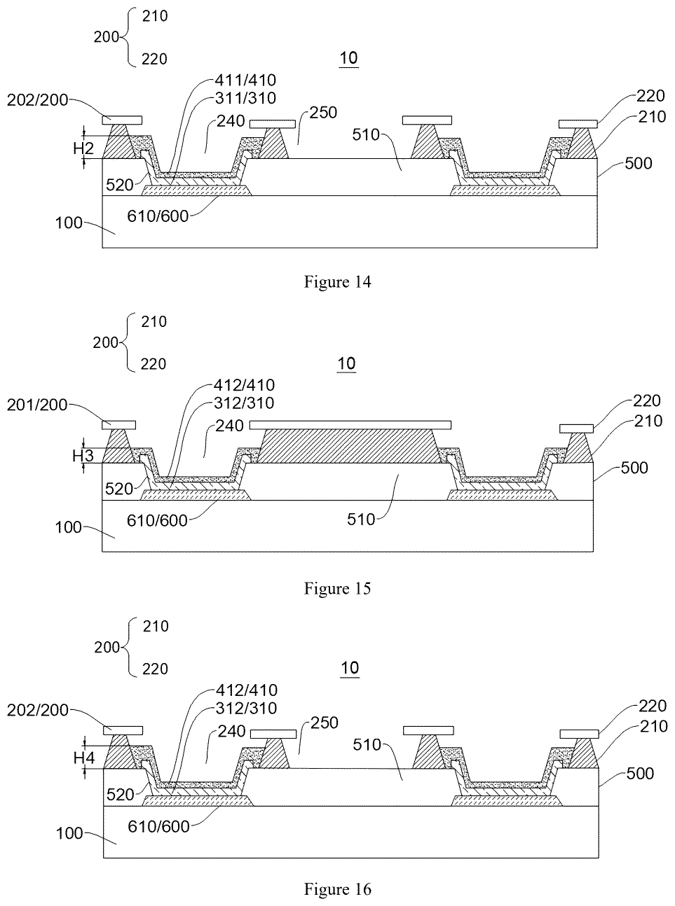

Referring to FIGS. 13 and 14, FIG. 13 is a partial cross-sectional view of a first active area according to still yet another embodiment; and FIG. 14 is a partial cross-sectional view of a second active area according to still yet another embodiment.

As shown in FIGS. 13 and 14, in some embodiments, the first electrode 410 includes a first sub-electrode 411 located on a side of the first light-emitting unit 311 that faces away from the substrate 100. In the first active area AA1, the climbing height H0 of the first sub-electrode 411 on the isolation structure 200 is a first height H1, and in the second active area AA2, the climbing height H0 of the first sub-electrode 411 on the isolation structure 200 is a second height H2, the first height H1 being less than or equal to the second height H2.

In these embodiments, the first height H1 is less than or equal to the second height H2. In other words, the climbing height H0, on the isolation structure 200, of the first sub-electrode 411 in the second active area AA2 is greater than or equal to the climbing height H0, on the isolation structure 200, of the first sub-electrode 411 in the first active area AA1, resulting in an increased lap area between the first sub-electrode 411 corresponding to the first light-emitting unit 311 in the second active area AA2 and the isolation structure 200, and a reduced lap impedance between the first sub-electrode 411 corresponding to the first light-emitting unit 311 in the second active area AA2 and the isolation structure 200. A difference between a lap impedance between the first sub-electrode 411 corresponding to the first light-emitting unit 311 in the first active area AA1 and the isolation structure 200 and a lap impedance between the first sub-electrode corresponding to the first light-emitting unit in the second active area AA2 and the isolation structure is reduced, thereby mitigating undesirable phenomenon of dark streaks appearing in the second active area AA2 due to a large difference between the lap impedance between the first sub-electrode 411 corresponding to the first light-emitting unit 311 in the first active area AA1 and the isolation structure 200 and the lap impedance between the first sub-electrode corresponding to the first light-emitting unit in the second active area AA2 and the isolation structure, and thus improving the usage performance of the display panel 10.

Referring to FIGS. 15 and 16, FIG. 15 is a partial cross-sectional view of a first active area according to still yet another embodiment; and FIG. 16 is a partial cross-sectional view of a second active area according to still yet another embodiment.

As shown in FIGS. 15 and 16, in some embodiments, the first electrode 410 further includes a second sub-electrode 412 located on a side of the second light-emitting unit 312 that faces away from the substrate 100. In the first active area AA1, the climbing height H0 of the second sub-electrode 412 on the isolation structure 200 is a third height H3, and in the second active area AA2, the climbing height H0 of the second sub-electrode 412 on the isolation structure 200 is a fourth height H4, the third height H3 being less than or equal to the fourth height H4.

In these embodiments, the third height H3 is less than or equal to the fourth height H4. In other words, the climbing height H0, on the isolation structure 200, of the second sub-electrode 412 in the second active area AA2 is greater than or equal to the climbing height H0, on the isolation structure 200, of the second sub-electrode 412 in the first active area AA1, resulting in an increased lap area between the second sub-electrode 412 corresponding to the second light-emitting unit 312 in the second active area AA2 and the isolation structure 200, and a reduced lap impedance between the second sub-electrode 412 corresponding to the second light-emitting unit 312 in the second active area AA2 and the isolation structure 200. A difference between a lap impedance between the second sub-electrode 412 corresponding to the second light-emitting unit 312 in the first active area AA1 and the isolation structure 200 and a lap impedance between the second sub-electrode corresponding to the second light-emitting unit in the second active area AA2 and the isolation structure is reduced, thereby mitigating undesirable phenomenon of dark streaks appearing in the second active area AA2 due to a large difference between the lap impedance between the second sub-electrode 412 corresponding to the second light-emitting unit 312 in the first active area AA1 and the isolation structure 200 and the lap impedance between the second sub-electrode corresponding to the second light-emitting unit in the second active area AA2 and the isolation structure, and thus improving the usage performance of the display panel 10.

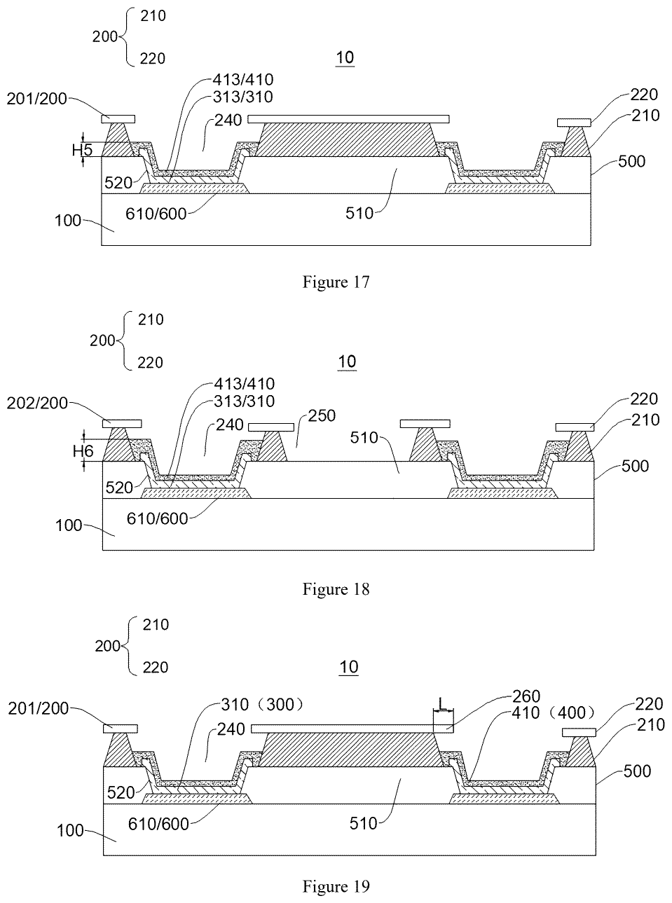

Referring to FIGS. 17 and 18, FIG. 17 is a partial cross-sectional view of a first active area according to still yet another embodiment; and FIG. 18 is a partial cross-sectional view of a second active area according to still yet another embodiment.

As shown in FIGS. 17 and 18, in some embodiments, the first electrode 410 further includes a third sub-electrode 413 located on a side of the third light-emitting unit 313 that faces away from the substrate 100. In the first active area AA1, the climbing height H0 of the third sub-electrode 413 on the isolation structure 200 is a fifth height H5, and in the second active area AA2, the climbing height H0 of the third sub-electrode 413 on the isolation structure 200 is a sixth height H6, the fifth height H5 being less than or equal to the sixth height H6.

In these embodiments, the fifth height H5 is less than or equal to the sixth height H6. In other words, the climbing height H0, on the isolation structure 200, of the third sub-electrode 413 in the second active area AA2 is greater than or equal to the climbing height H0, on the isolation structure 200, of the third sub-electrode 413 in the first active area AA1, resulting in an increased lap area between the third sub-electrode 413 corresponding to the third light-emitting unit 313 in the second active area AA2 and the isolation structure 200, and a reduced lap impedance between the third sub-electrode 413 corresponding to the third light-emitting unit 313 in the second active area AA2 and the isolation structure 200. A difference between a lap impedance between the third sub-electrode 413 corresponding to the third light-emitting unit 313 in the first active area AA1 and the isolation structure 200 and a lap impedance between the third sub-electrode corresponding to the third light-emitting unit in the second active area AA2 and the isolation structure is reduced, thereby mitigating undesirable phenomenon of dark streaks appearing in the second active area AA2 due to a large difference between the lap impedance between the third sub-electrode 413 corresponding to the third light-emitting unit 313 in the first active area AA1 and the isolation structure 200 and the lap impedance between the third sub-electrode corresponding to the third light-emitting unit in the second active area AA2 and the isolation structure, and thus improving the usage performance of the display panel 10.

As shown in FIGS. 2 and 3, in one embodiment, the first layer 210 has a first bottom surface 211 on a side close to the substrate 100, and the second layer 220 has a second bottom surface 221 on a side close to the substrate 100. A distance between an edge of an orthographic projection of the first bottom surface 211 on the substrate 100 that is close to the light-emitting unit 310 and an edge of an orthographic projection of the second bottom surface 221 on the substrate 100 that is close to the same light-emitting unit 310 is an extension distance DO. The extension distance DO corresponding to designated light-emitting units of the light-emitting units 310 in the second active area AA2 is less than or equal to the extension distance DO corresponding to other light-emitting units 310 in the first active area AA1 that emit the same color as the designated light-emitting units, that is, the distance between the edge of the orthographic projection of the first bottom surface 211 on the substrate 100 and the edge of the orthographic projection of the second bottom surface 221 on the substrate 100 that corresponds to the light-emitting unit 310 in the second active area AA2 is smaller, resulting in an increased lap area between the first electrode 410 in the second active area AA2 and the isolation structure 200 and a reduced lap impedance between the first electrode 410 in the second active area AA2 and the isolation structure 200.

The distance between the edge of the orthographic projection of the first bottom surface 211 on the substrate 100 and the edge of the orthographic projection of the second bottom surface 221 on the substrate 100 that corresponds to the light-emitting unit 310 is the distance between the edge of the orthographic projection of the first bottom surface 211 on the substrate 100 that is close to the light-emitting unit 310 and the edge of the orthographic projection of the second bottom surface 221 on the substrate 100 that is close to the light-emitting unit 310.

As shown in FIGS. 3 and 4, in some embodiments, the display panel 10 further includes: a second electrode layer 600 located between the substrate 100 and the isolation structure 200, the second electrode layer 600 including a plurality of second electrodes 610, where at least two of the second electrodes 610 in the second active area AA2 are electrically connected to each other by a connection line 620.

In one embodiment, an orthographic projection of the second electrode 610 on the substrate 100 overlaps the orthographic projection of the isolation opening 240 on the substrate 100.

In these embodiments, the orthographic projection of the second electrode 610 on the substrate 100 at least partially overlaps the orthographic projection of the isolation opening 240 on the substrate 100, that is, at least the second electrode 610 is exposed from the isolation opening 240 to serve as an electrode of the light-emitting unit 310 to ensure light emission of the light-emitting unit 310. One of the second electrode 610 and the first electrode 410 serves as an anode of the light-emitting unit 310, and the other serves as a cathode of the light-emitting unit 310. The embodiment of the present application is exemplified by taking the second electrode 610 as the anode of the light-emitting unit 310, and the first electrode 410 as the cathode of the light-emitting unit 310. At least two second electrodes 610 in the second active area AA2 are electrically connected to each other by the connection line 620, enabling one pixel drive circuit in the second active area AA2 to drive a plurality of second electrodes 610.

In one embodiment, at least two second electrodes 610 in the second active area AA2 form a second electrode group, and a plurality of second electrode groups are spaced and insulated from each other. A plurality of second electrodes 610 in the second electrode group are electrically connected to each other by the connection lines 620, enabling one pixel drive circuit to drive the plurality of second electrodes 610 in the second electrode group, with each pixel drive circuit driving the same number of second electrodes 610, thereby enhancing the display uniformity of the light-emitting unit 310. For example, three second electrodes 610 are connected to each other by the connection line 620 to form a second electrode group.

In one embodiment, an area of an orthographic projection, on the substrate 100, of the second electrode 610 in the first active area AA1 is greater than or equal to an area of an orthographic projection, on the substrate 100, of the second electrode 610 in the second active area AA2. Since the area of the isolation opening 240 in the first active area AA1 is greater than or equal to the area of the isolation opening 240 in the second active area AA2, the area of the second electrode 610 in the first active area AA1 is set to be greater than or equal to the area of the second electrode 610 in the second active area AA2, and the second electrode 610 is adapted to the isolation opening 240 to ensure light emission of the light-emitting unit 310.

In one embodiment, the orthographic projection, on the substrate 100, of the second electrode 610 in the first active area AA1 is polygonal, such as quadrilateral, which is adapted to the shape of the isolation opening 240 in the first active area AA1.

In one embodiment, the orthographic projection, on the substrate 100, of the second electrode 610 in the second active area AA2 is circular or elliptical, which is adapted to the shape of the isolation opening 240 in the second active area AA2.

As shown in FIGS. 2 to 4, in one embodiment, the isolation structure 200 includes a first isolation structure 201 located in the first active area AA1 and a plurality of second isolation structures 202 located in the second active area AA2, where the plurality of second isolation structures 202 are spaced apart from each other.

In one embodiment, the second isolation structures 202 encircle the isolation openings 240 located in the second active area AA2. The isolation openings 240 in the second active area AA2 are independent of each other, avoiding mutual influence between the first electrodes 410 in the isolation openings 240.

In one embodiment, the second isolation structure 202 is electrically connected to a signal line on a side close to the substrate 100, enabling an electrical signal to be provided to the second isolation structure 202.

In one embodiment, a light transmission gap 250 is formed between adjacent second isolation structures 202. The second isolation structures 202 in the second active area AA2 are spaced apart from each other to form the light transmission gap 250, thereby increasing the light transmission area of the second active area AA2, and thus improving the transmittance of the second active area AA2.

In one embodiment, the first isolation structure 201 encircles a first isolation opening, and the second isolation structure 202 encircles a second isolation opening. An area of an orthographic projection of the first isolation opening on the substrate 100 is greater than or equal to an area of an orthographic projection of the second isolation opening on the substrate 100, and the area of the orthographic projection, on the substrate 100, of the first electrode 410 formed by separation in the first active area AA1 is greater than or equal to the area of the orthographic projection, on the substrate 100, of the first electrode 410 formed by separation in the second active area AA2. The first electrode 410 in the first active area AA1 has a larger area, and has a larger lap area with the isolation structure 200. Therefore, the extension distance DO of the isolation structure 200 that corresponds to the light-emitting unit 310 in the second active area AA2 where the first electrode 410 is smaller is set to be smaller, resulting in an increased lap area between the first electrode 410 in the second active area AA2 and the isolation structure 200, and thus a reduced lap impedance between the first electrode 410 in the second active area AA2 and the isolation structure 200. A difference between a lap impedance between the first electrode 410 in the first active area AA1 and the isolation structure 200 and a lap impedance between the first electrode in the second active area AA2 and the isolation structure is reduced, thereby mitigating undesirable phenomenon of dark streaks appearing in the second active area AA2 due to a large difference between the lap impedance between the first electrode 410 in the first active area AA1 and the isolation structure 200 and the lap impedance between the first electrode in the second active area AA2 and the isolation structure, and thus improving the usage performance of the display panel 10.

In one embodiment, the orthographic projection of the first isolation opening on the substrate 100 has a polygonal structure, such as a quadrilateral structure.

In one embodiment, the orthographic projection of the second isolation opening on the substrate 100 is circular or elliptical. The circular or elliptical second isolation opening is easier to be made smaller, and thus the light transmission gap 250 in the second active area AA2 is easier to be made larger, thereby improving the light transmittance of the second active area AA2.

In one embodiment, the first isolation structure 201 and the second isolation structure 202 are spaced apart from each other, which further increases the light transmission area of the second active area AA2. In one embodiment, the first isolation structure 201 is in contact connection with the second isolation structure 202 to enable an electrical connection between the first isolation structure 201 and the second isolation structure 202.

In one embodiment, the first isolation structure 201 has a mesh structure, the first isolation structure 201 of the mesh structure encircles the first isolation opening, and the first isolation structures 201 are connected to each other throughout the structure, thereby implementing mutual conduction between the first electrodes 410 located in the first isolation opening, to form a continuous electrode.

In one embodiment, the width of the first isolation structure 201 is greater than or equal to the width of the second isolation structure 202. A smaller width is set for the second isolation structure 202, resulting in a reduced area of the second isolation structure 202 and an increased light transmission area of the second active area AA2. The width of the first isolation structure 201 is a dimension of the first isolation structure 201 in a direction in which two adjacent first isolation openings are disposed side by side, and the width of the second isolation structure 202 is a dimension of the second isolation structure 202 in a direction in which the second isolation opening points to the light transmission gap 250.

In one embodiment, a proportion of an area of an orthographic projection of the first isolation structure 201 on the substrate 100 to a proportion of an area of the first active area AA1 is a first ratio, and a proportion of an area of an orthographic projection of the second isolation structure 202 on the substrate 100 to a proportion of an area of the second active area AA2 is a second ratio, the first ratio being greater than or equal to the second ratio. The first ratio is a metal density of the first isolation structure 201 in the first active area AA1, and the second ratio is a metal density of the second isolation structure 202 in the second active area AA2. The first ratio is greater than or equal to the second ratio. The second active area AA2 has a lower metal density, resulting in a smaller proportion of area of the second isolation structure 202 and a larger proportion of light transmission area, thereby improving the light transmittance of the second active area AA2.

In some embodiments, the display panel 10 further includes: a pixel define layer 500 located on the substrate 100, the pixel define layer 500 including a pixel defining portion 510 and a pixel opening 520 encircled by the pixel defining portion 510, the pixel opening 520 being in communication with the isolation opening 240.

In these embodiments, the pixel opening 520 encircled by the pixel defining portion 510 is configured to define a light-emitting region of the display panel 10. The pixel opening 520 is communicatively connected with the isolation opening 240, to minimize obstruction of the isolation structure 200 to the pixel opening 520 and ensure the light emission effect of the display panel 10.

In some embodiments, the isolation structure 200 is located on a side of the pixel defining portion 510 that faces away from the substrate 100.

In these embodiments, the isolation structure 200 is disposed on the pixel defining portion 510, and the isolation structure 200 has a large height drop relative to the pixel opening 520. When the first electrode layer 400 is prepared, due to a large drop, the first electrode layer 400 is easier to break off at the isolation structure 200, thereby reducing the preparation difficulty of the first electrode layer 400.

In one embodiment, an area of an orthographic projection, on the substrate 100, of the pixel opening 520 in the first active area AA1 is greater than or equal to an area of an orthographic projection, on the substrate 100, of the pixel opening 520 in the second active area AA2. The size of the pixel opening 520 is adapted to the size of the isolation opening 240, and the pixel opening 520 can accommodate the light-emitting unit 310 of a corresponding size to ensure the light transmission area of the light-emitting unit 310.

In some embodiments, the second layer 220 includes a conductive material or an insulation material.

In these embodiments, the second layer 220 includes a conductive material, for example, the second layer 220 includes a non-metallic conductive material or a metallic conductive material. When the second layer 220 is made of a non-metallic conductive material or an insulation material, during wet etching of the first layer 210 with an etching solution, the second layer 220 is difficult to etch, thereby making it easier for the first layer 210 to be recessed relative to the second layer 220.

In some embodiments, the second layer 220 includes a metallic material, and the first layer 210 and the second layer 220 are made of different materials.

In these embodiments, when both the first layer 210 and the second layer 220 are made of the metallic material, the first layer 210 may be wet etched with an etching solution, and the etching solution is set to enable an etching rate of the second layer 220 to be less than an etching rate of the first layer 210. Since the first layer 210 has a greater etching rate, when wet etching is performed with the etching solution, the first layer 210 is etched faster even though the second layer 220 is subjected to some etching, which causes the first layer 210 to be recessed relative to the second layer 220.

Referring to FIG. 19, FIG. 19 is a partial cross-sectional view of a first active area according to still yet another embodiment.

As shown in FIG. 19, in some embodiments, the isolation structure 200 further includes a third layer 230 located on a side of the first layer 210 that faces the substrate 100, where an orthographic projection of the first layer 210 on the substrate 100 is within an orthographic projection of the third layer 230 on the substrate 100.

In these embodiments, since the first layer 210 is provided in order to obtain a recessed arrangement, the first layer 210 has a faster etching rate than the second layer 220 and the third layer 230 during etching, forming a recessed first layer 210. Since the etching rate of the first layer 210 is higher, more waste is generated during the etching and is likely to enter other locations of the display panel 10, thus causing an adverse effect. After the third layer 230 is provided, the first layer 210 may be better adhered to the third layer 230, and the generated etching waste falls on the third layer 230 to facilitate removal.

In one embodiment, the material of the second layer 220 is titanium (Ti), the material of the first layer 210 is aluminum (Al), and the material of the third layer 230 is titanium (Ti) or molybdenum (Mo), that is, the isolation structure 200 is made of a three-layer metal composite material of Ti/Al/Ti (titanium/aluminum/titanium) or Ti/Al/Mo (titanium/aluminum/molybdenum).

The composition, preparation, and the like of the isolation structure 200 are further described in Patent No. CN 118251982 A, US202410864269.8, Patent No. PCT/CN2024/098407, Patent No. PCT/CN2024/102783, Patent No. PCT/CN2024/098217, Patent No. PCT/CN2024/099419, and Patent No. PCT/CN2024/099072 for reference.

In one embodiment, the light-emitting layer 300 includes an electron injection layer (EIL), an electron transport layer (ETL), a light-emitting material layer, a hole injection layer (HIL), and a hole transport layer (HTL).

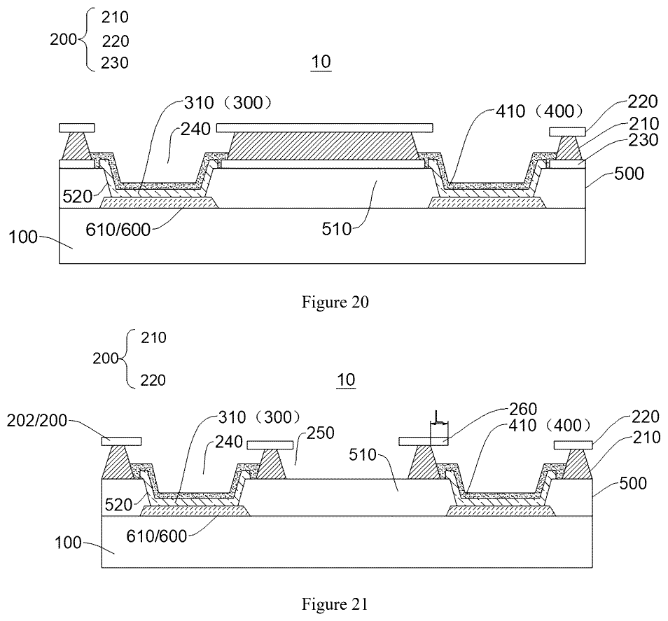

Referring to FIGS. 1, 20 and 21 together, FIG. 20 is a partial cross-sectional view of a first active area according to still yet another embodiment; and FIG. 21 is a partial cross-sectional view of a second active area according to still yet another embodiment.

As shown in FIGS. 1, 20 and 21, an embodiment of a second aspect of the present application provides a display panel 10, where the display panel 10 includes a first active area AA1 and a second active area AA2 adjacent to the first active area AA1. The display panel 10 further includes: a substrate 100; at least an isolation structure 200 located on the substrate 100, where the at least an isolation structure 200 encircles a plurality of isolation openings 240, and the isolation structure 200 includes a first layer 210 and a second layer 220 located on a side of the first layer 210 that faces away from the substrate 100, the second layer 220 including a protrusion 260 that protrudes relative to the first layer 210; and a light-emitting layer 300 located on the substrate 100, the light-emitting layer 300 including light-emitting units 310 located in the isolation openings 240, where a width L of the protrusion corresponding to designated light-emitting units of the light-emitting units 310 in the second active area AA2 is less than or equal to a width L of the protrusion corresponding to other light-emitting units 310 in the first active area AA1 that emit the same color as the designated light-emitting units.

The width L of the protrusion is a dimension of the protrusion 260 in a direction in which adjacent isolation openings 240 are disposed side by side, and the width L of the protrusion corresponding to the light-emitting unit 310 is a width L of the protrusion on the peripheral side of the isolation opening 240 in which the light-emitting unit 310 is located, that is, the width of the protrusion 260 on a side close to the light-emitting unit 310.

According to the display panel 10 of the embodiment of the present application, the display panel 10 includes the substrate 100, the isolation structure 200, and the light-emitting layer 300. The second active area AA2 is configured to accommodate a photosensitive assembly, and the second active area AA2 has a light transmittance greater than or equal to a light transmittance of the first active area AA1, thereby improving the photosensitive effect of the second active area AA2. The first layer 210 and the second layer 220 are disposed to form the isolation structure 200, an orthographic projection, on the substrate 100, of the first layer 210 disposed close to the substrate 100 is within an orthographic projection of the second layer 220 on the substrate 100, the area of the second layer 220 is greater than or equal to the area of the first layer 210, and the second layer 220 covers the surface of the first layer 210 that is close to the second layer 220, in which case the first layer 210 is recessed relative to the second layer 220 in a direction facing away from the isolation opening 240. The width L of the protrusion corresponding to designated light-emitting units of the light-emitting units 310 in the second active area AA2 is less than or equal to the width L of the protrusion corresponding to other light-emitting units 310 in the first active area AA1 that emit the same color as the designated light-emitting units. When the first electrode 410 is prepared, the peripheral side of the first electrode 410 laps a sidewall of the first layer 210 of the isolation structure 200. The width L of the protrusion corresponding to the light-emitting unit 310 in the second active area AA2 is smaller, resulting in an increased lap area between the first electrode 410 in the second active area AA2 and the isolation structure 200, and thus a reduced lap impedance between the first electrode 410 in the second active area AA2 and the isolation structure 200. A difference between a lap impedance between the first electrode 410 in the first active area AA1 and the isolation structure 200 and a lap impedance between the first electrode in the second active area AA2 and the isolation structure is reduced, thereby mitigating undesirable phenomenon of dark streaks appearing in the second active area AA2 due to a large difference between the lap impedance between the first electrode 410 in the first active area AA1 and the isolation structure 200 and the lap impedance between the first electrode in the second active area AA2 and the isolation structure, and thus improving the usage performance of the display panel 10.

As shown in FIGS. 11 and 12, an embodiment of a third aspect of the present application provides a display panel 10, where the display panel 10 includes a first active area AA1 and a second active area AA2, the first active area AA1 having a light transmittance lower than a light transmittance of the second active area AA2. The display panel 10 includes: a substrate 100; at least an isolation structure 200 located on the substrate 100, where the at least an isolation structure 200 encircles a plurality of isolation openings 240; a light-emitting layer 300 located on the substrate 100, the light-emitting layer 300 including a plurality of light-emitting units 310 located in the isolation openings 240; and a first electrode layer 400 located on a side of the light-emitting layer 300 that faces away from the substrate 100, the first electrode layer 400 including a plurality of first electrodes 410 spaced apart from each other, where the first electrodes 410 are electrically connected to the at least an isolation structure 200. Among the corresponding first electrodes 410 where the light-emitting units 310 of the same color are located, a climbing height H0, on the isolation structure 200, of the first electrode 410 located in the first active area AA1 is less than or equal to a climbing height H0, on the isolation structure 200, of the first electrode 410 located in the second active area AA2.

According to the display panel 10 of the embodiment of the present application, the display panel 10 includes the substrate 100, the isolation structure 200, and the light-emitting layer 300. The second active area AA2 is configured to accommodate a photosensitive assembly, and the second active area AA2 has a light transmittance greater than or equal to a light transmittance of the first active area AA1, thereby improving the photosensitive effect of the second active area AA2. The light-emitting layer 300 is difficult to connect at the edge of the isolation structure 200, resulting in breakage. The light-emitting layer 300 breaks to form light-emitting units 310 that are disconnected from each other, thereby reducing crosstalk of carriers in the light-emitting layer 300, and improving the display effect of the display panel 10; and the light-emitting unit 310 may be prepared without the use of a precision mask, reducing the development and use of the precision mask and lowering the preparation cost. The first electrode 410 in the isolation opening 240 that is located in the second active area AA2 has a larger climbing height H0 on the isolation structure 200, resulting in an increased lap area between the first electrode 410 in the second active area AA2 and the isolation structure 200, and a reduced lap impedance between the first electrode 410 in the second active area AA2 and the isolation structure 200. A difference between a lap impedance between the first electrode 410 in the first active area AA1 and the isolation structure 200 and a lap impedance between the first electrode in the second active area AA2 and the isolation structure is reduced, thereby mitigating undesirable phenomenon of dark streaks appearing in the second active area AA2 due to a large difference between the lap impedance between the first electrode 410 in the first active area AA1 and the isolation structure 200 and the lap impedance between the first electrode in the second active area AA2 and the isolation structure, and thus improving the usage performance of the display panel 10.

As for the structural design in this embodiment, it can be applied to other display panels 10, which can be selected according to actual situations, and this is not specifically limited in the present application.

An embodiment of a fourth aspect of the present application further provides a display apparatus, including a display panel 10 of any one of the above-described embodiments. Since the display apparatus according to the embodiment of the third aspect of the present application includes a display panel 10 according to any one of the above-described embodiments, the display apparatus according to the embodiment of the third aspect of the present application has the beneficial effects of the display panel 10 according to any one of the above-described embodiments, which will not be repeated herein.

The display apparatus in the embodiment of the present application includes, but is not limited to, devices having a display function, such as a cell phone, a personal digital assistant (PDA), a tablet computer, an e-book reader, a television, an access control system, a smart fixed-line telephone, or a console.

Referring to FIGS. 1 to 22, FIG. 22 is a schematic flowchart of a preparation method for a display panel according to an embodiment of the present application.

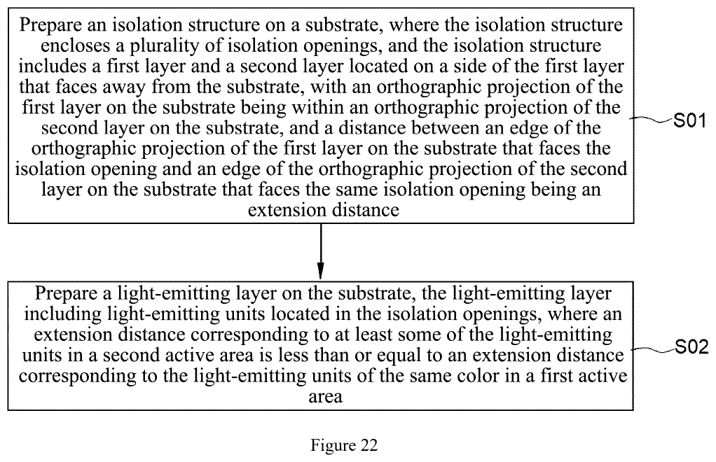

An embodiment of a fifth aspect of the present application further provides a preparation method for a display panel 10. The display panel 10 may be a display panel 10 according to any one of the above-described embodiments. The display panel 10 includes a first active area AA1 and a second active area AA2 adjacent to the first active area AA1. As shown in FIG. 22, the preparation method includes:
step S01: preparing at least an isolation structure 200 on a substrate 100, where the at least an isolation structure 200 encircles a plurality of isolation openings 240, and the isolation structure 200 includes a first layer 210 and a second layer 220 located on a side of the first layer 210 that faces away from the substrate 100, with an orthographic projection of the first layer 210 on the substrate 100 being within an orthographic projection of the second layer 220 on the substrate 100; and a distance between an edge of the orthographic projection of the first layer 210 on the substrate 100 that faces the isolation opening 240 and an edge of the orthographic projection of the second layer 220 on the substrate 100 that faces the same isolation opening 240 being an extension distance D0; and
step S02: preparing a light-emitting layer 300 on the substrate 100, the light-emitting layer 300 including a plurality of light-emitting units 310 located in the isolation openings 240, where the extension distance D0 corresponding to designated light-emitting units of the light-emitting units 310 in the second active area AA2 is less than or equal to the extension distance D0 corresponding to other light-emitting units 310 in the first active area AA1 that emit the same color as the designated light-emitting units.

In the preparation method according to the embodiment of the fourth aspect of the present application, the at least an isolation structure 200 is prepared by step S01. The first layer 210 and the second layer 220 are disposed to form the isolation structure 200, an orthographic projection, on the substrate 100, of the first layer 210 disposed close to the substrate 100 is within an orthographic projection of the second layer 220 on the substrate 100, the area of the second layer 220 is greater than or equal to the area of the first layer 210, and the second layer 220 covers the surface of the first layer 210 that is close to the second layer 220, in which case the first layer 210 is recessed relative to the second layer 220 in a direction facing away from the isolation opening 240. When the light-emitting layer 300 is prepared, the light-emitting layer 300 causes a large drop at an edge of the isolation structure 200, the first layer 210 is recessed relative to the second layer 220, and the light-emitting layer 300 is difficult to connect at the edge of the isolation structure 200, resulting in breakage. The light-emitting layer 300 breaks to form light-emitting units 310 that are disconnected from each other, thereby reducing crosstalk of carriers in the light-emitting layer 300, and improving the display effect of the display panel 10; and the light-emitting unit 310 may be prepared without the use of a precision mask, reducing the development and use of the precision mask and lowering the preparation cost. The light-emitting layer 300 is prepared by step S02. The extension distance D0 corresponding to designated light-emitting units of the light-emitting units 310 in the second active area AA2 is less than or equal to the extension distance D0 corresponding to other light-emitting units 310 in the first active area AA1 that emit the same color as the designated light-emitting units. When a first electrode 410 is prepared, the peripheral side of the first electrode 410 laps a sidewall of the first layer 210 of the isolation structure 200. The extension distance D0 of the isolation structure 200 corresponding to the light-emitting units 310 in the second active area AA2 is smaller, resulting in an increased lap area between the first electrode 410 in the second active area AA2 and the isolation structure 200, and thus a reduced lap impedance between the first electrode 410 in the second active area AA2 and the isolation structure 200. A difference between a lap impedance between the first electrode 410 in the first active area AA1 and the isolation structure 200 and a lap impedance between the first electrode in the second active area AA2 and the isolation structure is reduced, thereby mitigating undesirable phenomenon of dark streaks appearing in the second active area AA2 due to a large difference between the lap impedance between the first electrode 410 in the first active area AA1 and the isolation structure 200 and the lap impedance between the first electrode in the second active area AA2 and the isolation structure, and thus improving the usage performance of the display panel 10.

In some embodiments, in step S01, the method includes:
preparing an isolation material layer on the substrate 100; and
simultaneously patterning the isolation material layer located in the first active area AA1 and the second active area AA2 by using a first mask, to form a first isolation opening 240 located in the first active area AA1, and a second isolation opening 240 and a light transmission gap 250 that are located in the second active area AA2.

In these embodiments, the isolation material layer in the first active area AA1 and the second active area AA2 is patterned at the same time by using the same mask, and the extension distance D0 corresponding to the designated light-emitting units 310 in the second active area AA2 is less than or equal to the extension distance D0 corresponding to the light-emitting units 310 in the first active area AA1 that emit the same color as the designated light-emitting units, resulting in an increased lap area between the first electrode 410 in the second active area AA2 and the isolation structure 200, and thus a reduced lap impedance between the first electrode 410 in the second active area AA2 and the isolation structure 200. A difference between a lap impedance between the first electrode 410 in the first active area AA1 and the isolation structure 200 and a lap impedance between the first electrode in the second active area AA2 and the isolation structure is reduced, thereby mitigating undesirable phenomenon of dark streaks appearing in the second active area AA2 due to a large difference between the lap impedance between the first electrode 410 in the first active area AA1 and the isolation structure 200 and the lap impedance between the first electrode in the second active area AA2 and the isolation structure, and thus improving the usage performance of the display panel 10.

In one embodiment, the step of performing patterned processing simultaneously on the isolation material layer located in the first active area AA1 and the second active area AA2 by using a first mask includes:
performing dry etching on the isolation material layer located in the first active area AA1 and the second active area AA2 by using the first mask; and
performing wet etching on the isolation material layer located in the first active area AA1 and the second active area AA2 by using a wet etching solution.

In these embodiments, when the wet etching solution is used to perform wet etching on the isolation material layer in the first active area AA1 and the second active area AA2, only the first isolation opening 240 needs to be formed by etching using the wet etching solution in the first active area AA1, while both the second isolation opening 240 and the light transmission gap 250 need to be formed by etching using the wet etching solution in the second active area AA2. In this case, in the second active area AA2, part of the wet etching solution is used to perform etching on the isolation material layer at the position of the light transmission gap 250, and the other part of the wet etching solution is used to perform etching on the isolation material layer at the position of the second isolation opening 240. Therefore, the amount of wet etching solution used to perform etching to form the second isolation opening 240 is less than the amount of wet etching solution used to perform etching to form the first isolation opening 240, and a lateral etching level of the second isolation opening 240 is reduced, that is, the extension distance D0 corresponding to the designated light-emitting units 310 in the second active area AA2 is less than or equal to the extension distance D0 corresponding to the light-emitting units 310 in the first active area AA1 that emit the same color as the designated light-emitting units, resulting in an increased lap area between the first electrode 410 in the second active area AA2 and the isolation structure 200, and thus a reduced lap impedance between the first electrode 410 in the second active area AA2 and the isolation structure 200. A difference between a lap impedance between the first electrode 410 in the first active area AA1 and the isolation structure 200 and a lap impedance between the first electrode in the second active area AA2 and the isolation structure is reduced, thereby mitigating undesirable phenomenon of dark streaks appearing in the second active area AA2 due to a large difference between the lap impedance between the first electrode 410 in the first active area AA1 and the isolation structure 200 and the lap impedance between the first electrode in the second active area AA2 and the isolation structure, and thus improving the usage performance of the display panel 10.

In some embodiments, in step S01, the method includes:
preparing an isolation material layer on the substrate 100;
patterning the isolation material layer located in the first active area AA1 by using a second mask for a first time period; and
patterning the isolation material layer located in the second active area AA2 by using a third mask for a second time period, where the first time period is greater than or equal to the second time period.

In these embodiments, the isolation material layer located in the first active area AA1 and the second active area AA2 is patterned respectively by using different masks, and the time for patterning of the isolation material layer in the first active area AA1 is longer than the time for patterning of the isolation material layer in the second active area AA2, and the extension distance D0 corresponding to the designated light-emitting units 310 in the second active area AA2 is less than or equal to the extension distance D0 corresponding to the light-emitting units 310 in the first active area AA1 that emit the same color as the designated light-emitting units, resulting in an increased lap area between the first electrode 410 in the second active area AA2 and the isolation structure 200, and thus a reduced lap impedance between the first electrode 410 in the second active area AA2 and the isolation structure 200. A difference between a lap impedance between the first electrode 410 in the first active area AA1 and the isolation structure 200 and a lap impedance between the first electrode in the second active area AA2 and the isolation structure is reduced, thereby mitigating undesirable phenomenon of dark streaks appearing in the second active area AA2 due to a large difference between the lap impedance between the first electrode 410 in the first active area AA1 and the isolation structure 200 and the lap impedance between the first electrode in the second active area AA2 and the isolation structure, and thus improving the usage performance of the display panel 10.

The embodiments of the present application as described above neither set forth all the details, nor do they limit the present disclosure to only the described specific embodiments. Apparently, many modifications and variations can be made in light of the above description. The embodiments are selected and described in this specification to better explain the principles and practical applications of the present application, and those skilled in the art can make good use of the present application and modify and use the present application. The present application is limited only by the claims and all the scopes and equivalents thereof.

1. A display panel, which comprises a first active area and a second active area, wherein the first active area has a light transmittance less than a light transmittance of the second active area, the display panel comprising:
a substrate;
at least an isolation structure located on the substrate, wherein the at least an isolation structure encircles a plurality of isolation openings, and the at least an isolation structure comprises a first layer and a second layer located on a side of the first layer that faces away from the substrate, with an orthographic projection of the first layer on the substrate being within an orthographic projection of the second layer on the substrate; and
a light-emitting layer located on the substrate, the light-emitting layer comprising a plurality of light-emitting units located in the isolation openings,
wherein a distance between an edge of the orthographic projection of the first layer on the substrate that is close to the light-emitting unit and an edge of the orthographic projection of the second layer on the substrate that is close to the same light-emitting unit is an extension distance, and the extension distance corresponding to designated light-emitting units of the plurality of light-emitting units in the second active area is less than or equal to the extension distance corresponding to other light-emitting units in the first active area that emit the same color as the designated light-emitting units.

2. The display panel according to claim 1, wherein the extension distances corresponding to a plurality of light-emitting units of the same color in the first active area are the same, or the extension distances corresponding to a plurality of light-emitting units of the same color in the second active area are the same,
or the extension distances corresponding to a plurality of light-emitting units of the same color in the first active area are the same, and the extension distances corresponding to a plurality of light-emitting units of the same color in the second active area are the same.

3. The display panel according to claim 1, wherein among the isolation openings corresponding to at least some of the light-emitting units of the same color, an area of an orthographic projection, on the substrate, of the isolation opening located in the first active area is greater than or equal to an area of an orthographic projection, on the substrate, of the isolation opening located in the second active area.

4. The display panel according to claim 1, further comprising:
a first electrode layer located on a side of the light-emitting layer that faces away from the substrate,
the first electrode layer comprising a plurality of first electrodes spaced apart from each other, wherein the first electrodes are electrically connected to the at least an isolation structure;
an orthographic projection of each of the light-emitting units on the substrate is within an orthographic projection of each of the first electrodes on the substrate; and
the light-emitting units and the at least an isolation structure are spaced apart from each other.

5. The display panel according to claim 4, wherein an area of an orthographic projection, on the substrate, of the first electrode in the first active area is greater than or equal to an area of an orthographic projection, on the substrate, of the first electrode in the second active area.

6. The display panel according to claim 4, wherein among the corresponding first electrodes where the light-emitting units of the same color are located, a climbing height, on the at least an isolation structure, of the first electrode located in the first active area is less than or equal to a climbing height, on the at least an isolation structure, of the first electrode located in the second active area.

7. The display panel according to claim 1, wherein the first layer has a first bottom surface on a side close to the substrate, and the second layer has a second bottom surface on a side close to the substrate, wherein a distance between an edge of an orthographic projection of the first bottom surface on the substrate that is close to the light-emitting unit and an edge of an orthographic projection of the second bottom surface on the substrate that is close to the same light-emitting unit is an extension distance.

8. The display panel according to claim 1, further comprising:
a second electrode layer located between the substrate and the at least an isolation structure, the second electrode layer comprising a plurality of second electrodes, wherein at least two of the second electrodes in the second active area are electrically connected to each other by a connection line.

9. The display panel according to claim 8, wherein at least two of the second electrodes in the second active area form a second electrode group, and a plurality of second electrode groups are spaced apart and insulated from each other.

10. The display panel according to claim 8, wherein an area of an orthographic projection, on the substrate, of the second electrode in the first active area is greater than or equal to an area of an orthographic projection, on the substrate, of the second electrode in the second active area.

11. The display panel according to claim 1, wherein the at least an isolation structure comprises a first isolation structure located in the first active area and a plurality of second isolation structures located in the second active area, wherein the plurality of second isolation structures are spaced apart from each other;
each of the second isolation structures encircles the isolation opening located in the second active area; and
a light transmission gap is formed between adjacent second isolation structures.

12. The display panel according to claim 10, wherein the first isolation structure encircles a first isolation opening, and the second isolation structure encircles a second isolation opening, wherein an area of an orthographic projection of the first isolation opening on the substrate is greater than or equal to an area of an orthographic projection of the second isolation opening on the substrate.

13. The display panel according to claim 11,
further comprising a signal line located between the substrate and the second isolation structure, and the second isolation structure is electrically connected to the signal line.

14. The display panel according to claim 11, wherein
the first isolation structure and the second isolation structure are spaced apart from each other;
the first isolation structure has a mesh structure;
a width of the first isolation structure is greater than or equal to a width of the second isolation structure; and
a proportion of an area of an orthographic projection of the first isolation structure on the substrate to a proportion of an area of the first active area is a first ratio, and a proportion of an area of an orthographic projection of the second isolation structure on the substrate to a proportion of an area of the second active area is a second ratio, the first ratio being greater than or equal to the second ratio.

15. The display panel according to claim 1, further comprising:
a pixel define layer located on the substrate, the pixel define layer comprising a pixel defining portion and a pixel opening encircled by the pixel defining portion, the pixel opening being in communication with the isolation opening; and
the isolation structure being located on a side of the pixel defining portion that faces away from the substrate.

16. The display panel according to claim 15, wherein an area of an orthographic projection, on the substrate, of the pixel opening in the first active area is greater than or equal to an area of an orthographic projection, on the substrate, of the pixel opening in the second active area.

17. A display panel, which comprises a first active area and a second active area adjacent to the first active area, the display panel further comprising:
a substrate;
at least an isolation structure located on the substrate, wherein the at least an isolation structure encircles a plurality of isolation openings, and the isolation structure comprises a first layer and a second layer located on a side of the first layer that faces away from the substrate, the second layer comprising a protrusion that protrudes relative to the first layer; and
a light-emitting layer located on the substrate, the light-emitting layer comprising a plurality of light-emitting units located in the isolation openings,
wherein a width of the protrusion corresponding to designated light-emitting units of the plurality of light-emitting units in the second active area is less than or equal to a width of the protrusion corresponding to other light-emitting units in the first active area that emit the same color as the designated light-emitting units.

18. The display panel according to claim 17, wherein widths of the protrusions of a plurality of light-emitting units of the same color in the first active area are the same, or widths of the protrusions of a plurality of light-emitting units of the same color in the second active area are the same,
or widths of the protrusions of a plurality of light-emitting units of the same color in the first active area are the same, and widths of the protrusions of a plurality of light-emitting units of the same color in the second active area are the same.

19. A display panel, which comprises a first active area and a second active area, wherein the first active area has a light transmittance less than a light transmittance of the second active area, the display panel comprising:
a substrate;
at least an isolation structure located on the substrate, wherein the at least an isolation structure encircles a plurality of isolation openings;
a light-emitting layer located on the substrate, the light-emitting layer comprising a plurality of light-emitting units located in the isolation openings; and
a first electrode layer located on a side of the light-emitting layer that faces away from the substrate, the first electrode layer comprising a plurality of first electrodes spaced apart from each other, wherein the first electrodes are electrically connected to the at least an isolation structure; and
among the corresponding first electrodes where the light-emitting units of the same color are located, a climbing height, on the at least an isolation structure, of the first electrode located in the first active area is less than or equal to a climbing height, on the at least an isolation structure, of the first electrode located in the second active area.
